(19) United States
(12) Patent Application Publication
(10) Pub. No.: US 2025/0210415 A1
(43) Pub. Date: Jun. 26, 2025

(54) MANUFACTURING METHOD OF SEMICONDUCTOR STRUCTURE

(71) Applicant: Winbond Electronics Corp., Taichung City (TW)

(72) Inventor: Shih-Han Hung, Tainan City (TW)

(73) Assignee: Winbond Electronics Corp., Taichung City (TW)

(21) Appl. No.: 18/581,386

(22) Filed: Feb. 20, 2024

(30) Foreign Application Priority Data
Dec. 20, 2023 (TW) 112149857

(51) Int. Cl. H01L 21/768; H01L 21/3065; H01L 23/00

(52) U.S. Cl. CPC H01L 21/76898; H01L 21/3065; H01L 21/7682; H01L 21/76829; H01L 21/76838; H01L 24/03; H01L 24/11; H01L 2224/0231; H01L 2224/11

(57) ABSTRACT

A manufacturing method of a semiconductor structure including the following steps is provided. A substrate is provided. The substrate includes a front side and a back side opposite to each other. A device layer is formed on the front side of the substrate. A through-substrate via (TSV) is formed in the device layer and the substrate. The TSV extends from the front side of the substrate into the substrate. A first dielectric layer is formed between the TSV and the substrate. A patterning process is performed on the back side of the substrate to form an air gap. The air gap surrounds the TSV.

### CROSS-REFERENCE TO RELATED APPLICATION

This application claims the priority benefit of Taiwan application serial no. 112149857, filed on Dec. 20, 2023. The entirety of the above-mentioned patent application is hereby incorporated by reference herein and made a part of this specification.

### BACKGROUND

### Technical Field

The present disclosure relates to a method of manufacturing a semiconductor structure, and in particular, to a method of manufacturing a semiconductor structure including a through-substrate via (TSV).

### Description of Related Art

Some semiconductor structures have through-substrate vias (TSVs) through the substrate. TSVs may be used to electrically connect stacked integrated circuits together. However, as the size of semiconductor structures continues to shrink, TSVs will have adverse effects on semiconductor elements in the semiconductor structure.

### SUMMARY

The present disclosure provides a method for manufacturing a semiconductor structure, which may prevent through-substrate vias (TSVs) from adversely affecting semiconductor elements in the semiconductor structure.

In the disclosure, a manufacturing method of a semiconductor structure including the following steps is provided. A substrate is provided. The substrate includes a front side and a back side opposite to each other. A device layer is formed on the front side of the substrate. A through-substrate via (TSV) is formed in the device layer and the substrate. The TSV extends from the front side of the substrate into the substrate. A first dielectric layer is formed between the TSV and the substrate. A patterning process is performed on the back side of the substrate to form an air gap. The air gap surrounds the TSV.

Based on the above, in the manufacturing method of a semiconductor structure provided by the present disclosure, a patterning process is performed on the back side of the substrate to form an air gap. The air gap surrounds the TSV. In some embodiments, an air gap may be used to prevent TSV from adversely affecting semiconductor elements (e.g., transistor elements) in the semiconductor structure. In other embodiments, a filling layer may be formed in the air gap, and the filling layer may be used to prevent the TSV from adversely affecting semiconductor elements (e.g., transistor elements) in the semiconductor structure.

To make the above features and advantages of the disclosure more comprehensible, several embodiments accompanied with drawings are described in detail as follows.

### BRIEF DESCRIPTION OF THE DRAWINGS

FIG. 1A to FIG. 1L are cross-sectional views of a manufacturing process of a semiconductor structure according to some embodiments of the present disclosure.

FIG. 2 is a top view of the semiconductor structure of FIG. 1L.

FIG. 3A to FIG. 3C are cross-sectional views of a manufacturing process of a semiconductor structure according to other embodiments of the present disclosure.

FIG. 4 is a top view of the semiconductor structure of FIG. 3C.

### DESCRIPTION OF THE EMBODIMENTS

The invention will be more fully described with reference to the drawings of the embodiments. However, the invention may be embodied in a variety of different forms and should not be limited to the embodiments described herein. The thickness of layers and regions in the drawings may be exaggerated for clarity. The same or similar component numbers indicate the same or similar components. Accordingly, no further description thereof is provided hereinafter.

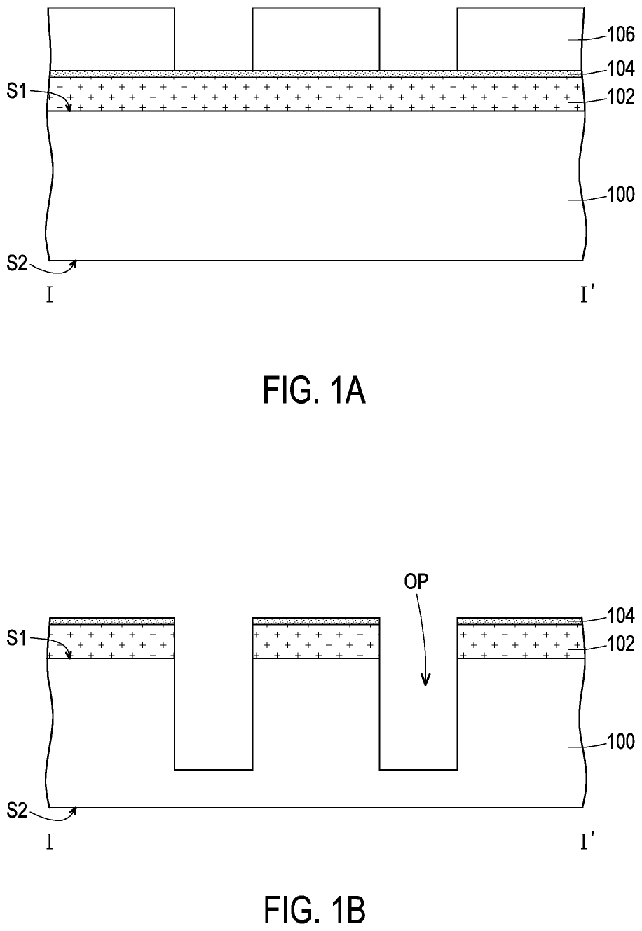

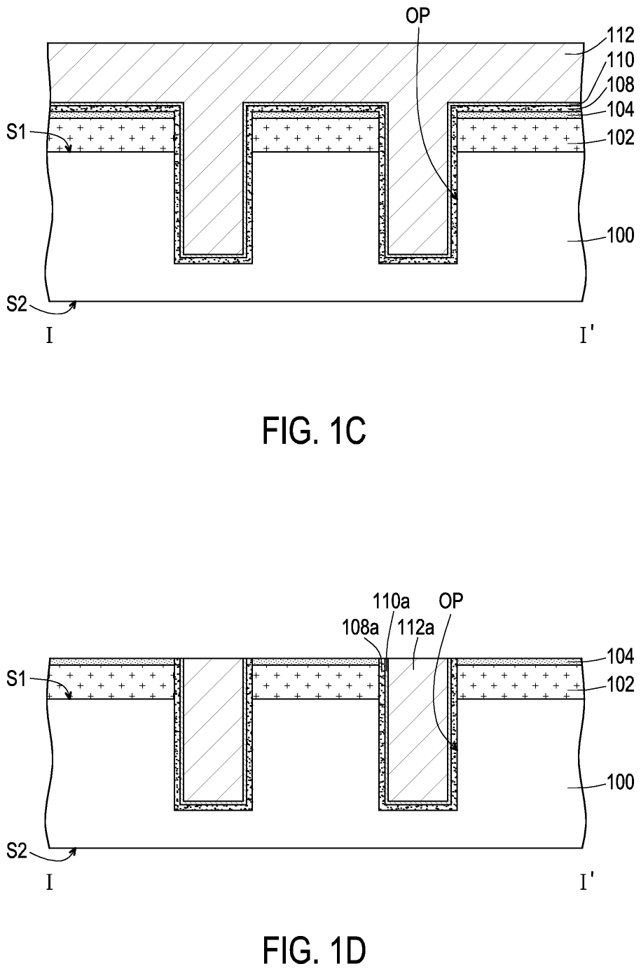

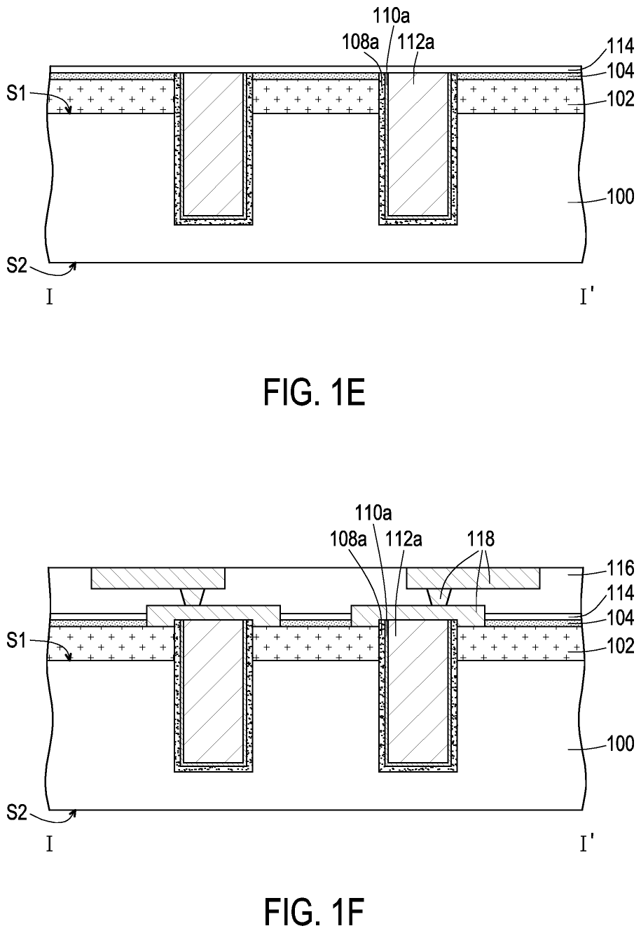

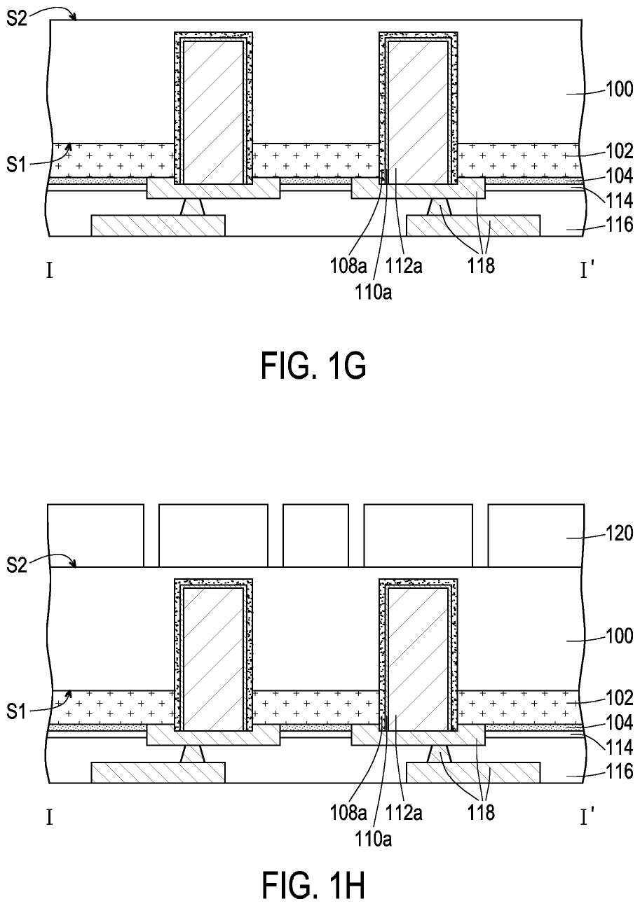

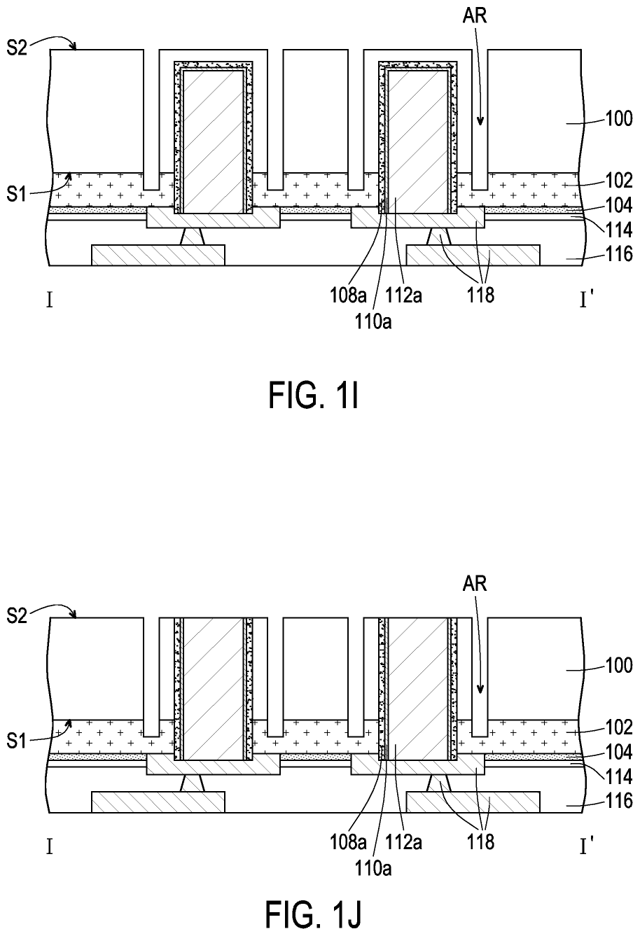

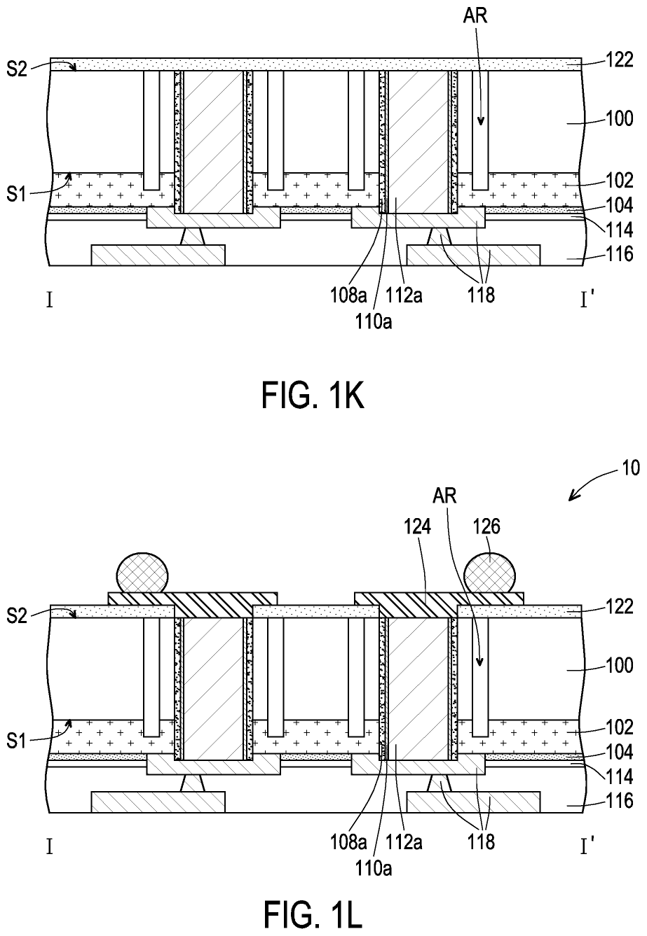

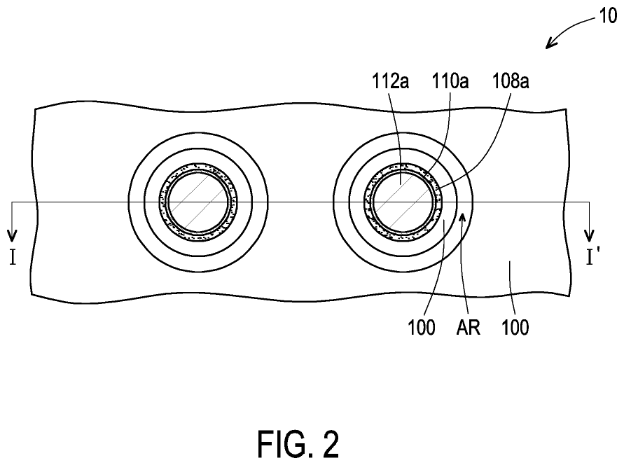

FIG. 1A to FIG. 1L are cross-sectional views of a manufacturing process of a semiconductor structure according to some embodiments of the present disclosure. FIG. 2 is a top view of the semiconductor structure of FIG. 1L. FIG. 1A to FIG. 1L are cross-sectional views along the line I-I′ in FIG. 2. In the top view of FIG. 2, some components in FIG. 1L are omitted to clearly illustrate the positional relationship between the components in FIG. 2.

Referring to FIG. 1A, a substrate 100 is provided. The substrate 100 includes a front side S1 and a back side S2 that are opposite to each other. The substrate 100 may be a semiconductor substrate, such as a silicon substrate. Next, a device layer 102 is formed on the front side S1 of the substrate 100. In some embodiments, the device layer 102 may include components such as a dielectric layer and a semiconductor element (e.g., active element and/or passive element) located in the dielectric layer, and description of the components is omitted here. Then, a stopping layer 104 may be formed on the device layer 102. The material of the stopping layer 104 may include nitride (e.g., silicon nitride). The formation method of the stopping layer 104 may include a chemical vapor deposition method. Next, a patterned photoresist layer 106 may be formed on the stopping layer 104. The patterned photoresist layer 106 may be formed by a photolithography process.

Referring to FIG. 1B, the patterned photoresist layer 106 may be used as a mask to remove part of the stopping layer 104, part of the device layer 102 and part of the substrate 100. In this way, the opening OP may be formed in the stopping layer 104, the device layer 102 and the substrate 100. The opening OP may extend from the front side S1 of the substrate 100 into the substrate 100. The removal method of part of the stopping layer 104, part of the device layer 102 and part of the substrate 100 may include dry etching.

Next, the patterned photoresist layer 106 may be removed. The removal method of the patterned photoresist layer 106 may include a dry stripping method or a wet stripping method.

Referring to FIG. 1C, a dielectric material layer 108 may be formed on the stopping layer 104 and in the opening OP. The material of dielectric material layer 108 may include an oxide (e.g., silicon oxide). The formation method of the dielectric material layer 108 may include an atomic layer deposition method.

Next, a barrier material layer 110 may be formed on the dielectric material layer 108. The material of the barrier material layer 110 may include tantalum (Ta), tantalum nitride (TaN), or a combination thereof. The barrier material layer 110 may be formed by a chemical vapor deposition method.

Then, a through-substrate via (TSV) material layer 112 may be formed on the barrier material layer 110. The material of the TSV material layer 112 may include copper. The formation method of the TSV material layer 112 may include electroplating.

Referring to FIG. 1D, the TSV material layer 112, the barrier material layer 110 and the dielectric material layer 108 located outside the opening OP may be removed to form the TSV 112a, the barrier layer 110a and the dielectric layer 108a. In this way, the TSV 112a may be formed in the device layer 102 and the substrate 100, the dielectric layer 108a may be formed between the TSV 112a and the substrate 100, and the barrier layer 110a may be formed between the TSV 112a and the dielectric layer 108a. The TSV 112a extends from the front side S1 of the substrate 100 into the substrate 100. The removal method of the TSV material layer 112, the barrier material layer 110 and the dielectric material layer 108 located outside the opening OP may include a chemical mechanical polishing method.

Referring to FIG. 1E, a protective layer 114 may be formed on the stopping layer 104, the TSV 112a, the barrier layer 110a and the dielectric layer 108a. The material of the protective layer 114 may include nitride (e.g., silicon nitride). The formation method of the protective layer 114 may be a chemical vapor deposition method.

Referring to FIG. 1F, a dielectric layer 116 may be formed on the protective layer 114. In some embodiments, the dielectric layer 116 may be a multi-layer structure. The material of dielectric layer 116 may include an oxide (e.g., silicon oxide). The formation method of the dielectric layer 116 may include a chemical vapor deposition method.

Next, an interconnect structure 118 may be formed in the dielectric layer 116. The interconnect structure 118 may pass through the protective layer 114 and be electrically connected to the TSV 112a. The interconnect structure 118 may include wires, vias, or a combination thereof. The material of the interconnect structure 118 may include copper, aluminum, tungsten, or combinations thereof. Moreover, the number of layers of the interconnect structure 118 is not limited to the number of layers shown in the figure, the interconnection structure 118 having at least one layer falls within the scope of the present disclosure. The interconnect structure 118 may be formed by an interconnect process.

Referring to FIG. 1G, a thinning process may be performed on the back side S2 of the substrate 100. The thinning process may include a chemical mechanical polishing process.

Referring to FIG. 1H, a patterned photoresist layer 120 may be formed on the back side S2 of the substrate 100. The patterned photoresist layer 120 may be formed by a photolithography process.

Referring to FIG. 1I, the patterned photoresist layer 120 may be used as a mask to remove part of the substrate 100. In this way, a patterning process may be performed on the back side S2 of the substrate 100 to form the air gap AR. As shown in FIG. 2, the air gap AR surrounds the TSV 112a. The method of removing part of the substrate 100 may include a dry etching method.

Next, the patterned photoresist layer 120 may be removed. The removal method of the patterned photoresist layer 120 may include a dry stripping method or a wet stripping method.

Referring to FIG. 1J, after the air gap AR is formed, part of the substrate 100, part of the dielectric layer 108a and part of the barrier layer 110a are removed from the back side S2 of the substrate 100 to expose the TSV 112a. After the TSV 112a is exposed, the TSV 112a may penetrate the substrate 100. The air gap AR may extend into the device layer 102. The method of removing part of the substrate 100, part of the dielectric layer 108a, and part of the barrier layer 110a may include performing an etching process, a chemical mechanical polishing process, or a combination thereof on the back side S2 of the substrate 100. The above etching process may include a dry etching process.

Referring to FIG. 1K, a dielectric layer 122 may be formed on the back side S2 of the substrate 100. The dielectric layer 122 may seal one end of the air gap AR. The dielectric layer 122 may be located on the TSV 112a, the barrier layer 110a, and the dielectric layer 108a. The material of the dielectric layer 122 may include nitride (e.g., silicon nitride). The formation method of the dielectric layer 122 may include a chemical vapor deposition method.

Referring to FIG. 1L, a redistribution layer (RDL) 124 is formed on the TSV 112a. In some embodiments, the redistribution layer 124 may pass through the dielectric layer 122 and be electrically connected to the TSV 112a. Part of the redistribution layer 124 may be located on the dielectric layer 122. The material of the redistribution layer 124 may include conductive materials such as copper. Next, bumps 126 may be formed on the redistribution layer 124. The bumps 126 may be electrically connected to the redistribution layer 124. The material of bumps 126 may include copper, nickel, gold, or combinations thereof.

Based on the above embodiments, it can be known that in the manufacturing method of the semiconductor structure 10, a patterning process is performed on the back side S2 of the substrate 100 to form the air gap AR. The air gap AR surrounds the TSV 112a. In this way, the air gap AR may be used to prevent the TSV 112a from causing adverse effects on the semiconductor elements (e.g., transistor elements) in the semiconductor structure 10. For example, the air gap AR may be used to reduce parasitic capacitance and prevent stress caused by the TSV 112a from adversely affecting the electrical performance of the semiconductor device.

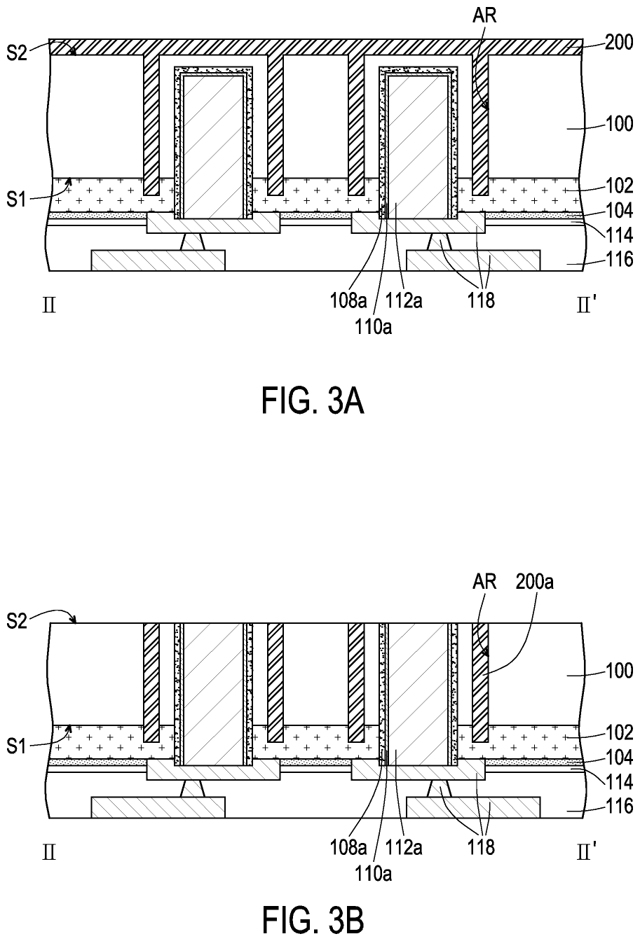

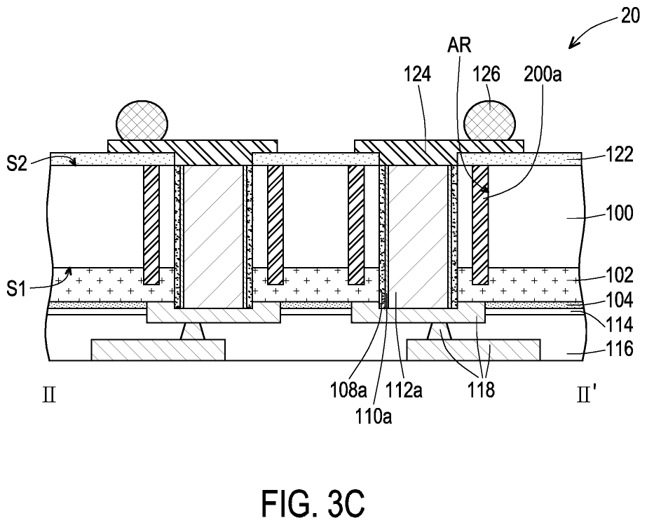

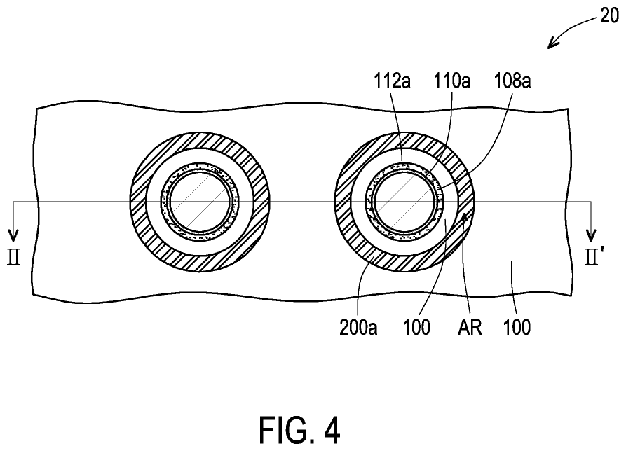

FIG. 3A to FIG. 3C are cross-sectional views of a manufacturing process of a semiconductor structure according to other embodiments of the present disclosure. FIG. 4 is a top view of the semiconductor structure of FIG. 3C. FIG. 3A to FIG. 3C are cross-sectional views along the line II-II′ in FIG. 4. In the top view of FIG. 4, some components in FIG. 3C are omitted to clearly illustrate the positional relationship between the components in FIG. 4.

Please refer to FIG. 3A, which provides a structure as shown in FIG. 1I. In addition, the structure of FIG. 1I and the manufacturing method thereof have been described in detail in the above embodiments and will not be described again.

After forming the air gap AR, a filling material layer 200 is formed on the back side S2 of the substrate 100 and in the air gap AR. The material of the filling material layer 200 may include dielectric materials (e.g., silicon oxide) or metallic materials (e.g., copper, tungsten). The formation method of the filling material layer 200 may be a chemical vapor deposition method or a physical vapor deposition method.

Referring to FIG. 3B, part of the filling material layer 200, part of the substrate 100, part of the dielectric layer 108a and part of the barrier layer 110a are removed from the back side S2 of the substrate 100, and a filling layer 200a is formed in the air gap AR and exposes the TSV 112a. As shown in FIG. 4, the filling layer 200a may surround the TSV 112a. The material of the filling layer 200a may include dielectric materials (e.g., silicon oxide) or metal materials (e.g., copper, tungsten). After the TSV 112a is exposed, the TSV 112a may penetrate the substrate 100. The method of removing part of the filling material layer 200, part of the substrate 100, part of the dielectric layer 108a and part of the barrier layer 110a may include performing an etching process, a chemical mechanical polishing process or a combination thereof on the back side S2 of the substrate 100. The above etching process may include a dry etching process.

Referring to FIG. 3C, the steps as shown in FIG. 1K and FIG. 1L may be performed to form the dielectric layer 122, the redistribution layer 124 and the bumps 126. The dielectric layer 122 may be located on the TSV 112a, the barrier layer 110a, the dielectric layer 108a and the filling layer 200a. For details of the dielectric layer 122, the redistribution layer 124 and the bumps 126, please refer to the description of FIG. 1K and FIG. 1L, and no repetition is incorporated.

Based on the above embodiments, it can be known that in the manufacturing method of the semiconductor structure 20, a patterning process is performed on the back side S2 of the substrate 100 to form the air gap AR. The air gap AR surrounds the TSV 112a. In the above embodiment, the filling layer 200a may be formed in the air gap AR, and the filling layer 200a may be used to prevent the TSV 112a from causing adverse effects on the semiconductor elements (e.g., transistor elements) in the semiconductor structure 20. For example, when the material of the filling layer 200a is a dielectric material, the filling layer 200a may be used to reduce the parasitic capacitance and prevent the stress caused by the TSV 112a from adversely affecting the electrical performance of the semiconductor device. Moreover, when the material of the filling layer 200a is a metal material, radio frequency interference may be prevented.

Although the present disclosure has been disclosed above through embodiments, it is not intended to limit the present disclosure. Anyone with ordinary knowledge in the technical field can make some modifications and refinement without departing from the spirit and scope of the present disclosure. Therefore, the scope to be protected by the present disclosure shall be determined by the appended claims.

What is claimed is:

1. A manufacturing method of a semiconductor structure, comprising:
providing a substrate, wherein the substrate comprises a front side and a back side opposite to each other;
forming a device layer on the front side of the substrate,
forming a through-substrate via (TSV) in the device layer and the substrate, wherein the TSV extends from the front side of the substrate into the substrate;
forming a first dielectric layer between the TSV and the substrate; and
performing a patterning process on the back side of the substrate to form an air gap, wherein the air gap surrounds the TSV.

2. The manufacturing method of the semiconductor structure according to claim 1, wherein performing the patterning process on the back side of the substrate comprises:
forming a patterned photoresist layer on the back side of the substrate; and
using the patterned photoresist layer as a mask and removing a portion of the substrate.

3. The manufacturing method of the semiconductor structure according to claim 1, wherein the method of removing the portion of the substrate comprises a dry etching method.

4. The manufacturing method of the semiconductor structure according to claim 1, wherein the air gap extends into the device layer.

5. The manufacturing method of the semiconductor structure according to claim 1, further comprising:
forming a barrier layer between the TSV and the first dielectric layer.

6. The manufacturing method of the semiconductor structure according to claim 5, further comprising:
forming a stopping layer on the device layer.

7. The manufacturing method of the semiconductor structure according to claim 6, wherein the method of forming the TSV, the barrier layer and the first dielectric layer comprises:
forming an opening in the stopping layer, the device layer and the substrate, wherein the opening extends into the substrate from the front side of the substrate;
forming a dielectric material layer on the stopping layer and in the opening;
forming a barrier material layer on the dielectric material layer;
forming a TSV material layer on the barrier material layer; and
removing the TSV material layer, the barrier material layer and the dielectric material layer located outside the opening to form the TSV, the barrier layer and the first dielectric layer.

8. The manufacturing method of the semiconductor structure according to claim 6, further comprising:
forming a protective layer on the stopping layer, the TSV, the barrier layer and the first dielectric layer;
forming a second dielectric layer on the protective layer; and
forming an interconnect structure in the second dielectric layer, wherein the interconnect structure passes through the protective layer and is electrically connected to the TSV.

9. The manufacturing method of the semiconductor structure according to claim 1, further comprising:
performing a thinning process on the back side of the substrate.

10. The manufacturing method of the semiconductor structure according to claim 9, wherein the thinning process comprises a chemical mechanical polishing process.

11. The manufacturing method of the semiconductor structure according to claim 1, further comprising:
after forming the air gap, removing a portion of the substrate and a portion of the first dielectric layer from the back side of the substrate to expose the TSV.

12. The manufacturing method of the semiconductor structure according to claim 11, wherein the method for removing the portion of the substrate and the portion of the first dielectric layer comprises performing an etching process, a chemical mechanical polishing process, or a combination thereof on the back side of the substrate.

13. The manufacturing method of the semiconductor structure according to claim 12, wherein the etching process comprises a dry etching process.

14. The manufacturing method of the semiconductor structure according to claim 11, wherein after the TSV is exposed, the TSV penetrates the substrate.

15. The manufacturing method of the semiconductor structure according to claim 1, further comprising:
forming a second dielectric layer on the back side of the substrate, wherein the second dielectric layer seals one end of the air gap.

16. The manufacturing method of the semiconductor structure according to claim 15, further comprising:
forming a redistribution layer on the TSV; and
forming a bump on the redistribution layer.

17. The manufacturing method of the semiconductor structure according to claim 16, wherein a portion of the redistribution layer is located on the second dielectric layer.

18. The manufacturing method of the semiconductor structure according to claim 1, further comprising:
forming a filling layer in the air gap, wherein the filling layer surrounds the TSV.

19. The manufacturing method of the semiconductor structure according to claim 18, wherein a material of the filling layer comprises a dielectric material or a metal material.

20. The manufacturing method of the semiconductor structure according to claim 1, further comprising:
after forming the air gap, forming a filling material layer on the back side of the substrate and in the air gap; and
removing a portion of the filling material layer, a portion of the substrate, and a portion of the first dielectric layer from the back side of the substrate to form a filling layer in the air gap and expose the TSV.
